(19) United States
(12) Patent Application Publication
(10) Pub. No.: US 2009/0113262 A1
(43) Pub. Date: Apr. 30, 2009

(54) SYSTEM AND METHOD FOR CONDITIONING AND IDENTIFYING BAD BLOCKS IN INTEGRATED CIRCUITS

(75) Inventors: Brandon Lee Fernandes, Santa Clara, CA (US); Benjamin Louie, Fremont, CA (US)

Correspondence Address: GROSSMAN, TUCKER, PERREAULT & PFLEGER, PLLC;c/o CPA Global, P. O. BOX 52050, MINNEAPOLIS, MN, 55402, US

(73) Assignee: INTEL CORPORATION, Santa Clara, CA (US)

(21) Appl. No.: 11/862,894

(22) Filed: Sep. 27, 2007

(51) Int. Cl. G01R 31/3177; G06F 11/25

(52) U.S. Cl. 714/726; 714/E11.155

(57) ABSTRACT

An electronic system of an Integrated circuit (IC) for conditioning and identification of bad blocks in the IC is disclosed. The electronic system includes at least one cyclic scan chain and at least one multiplexer. A cyclic scan chain includes a plurality of flip-flops, which are connected in a cascaded manner. A multiplexer is connected between two adjacent flip-flops of the cyclic shift register. The multiplexer has a first input pin connected to output of a first flip-flop, a second input pin connected to a user pin and an output pin connected to an input of a second flip-flop. The multiplexer is configured to condition the plurality of flip-flops through the user pin by programming logic bits in the plurality of flip-flop. The output of the first flip-flop is configured to read the logic bits in the plurality of flip-flops to identify a bad block in the IC.

### FIELD

The present disclosure generally relates to integrated circuits, and, more particularly, to a system and method for conditioning and identifying bad blocks in an Integrated Circuit (IC).

### BRIEF DESCRIPTION OF THE DRAWINGS

The advantages and features of the present disclosure will become better understood with reference to the following detailed description and claims taken in conjunction with the accompanying drawings, wherein like elements are identified with like symbols, and in which:

FIG. 1 is a circuit diagram illustrating a prior art circuit used for a reading operation for identifying bad blocks in an Integrated Circuit (IC);

FIGS. 2A and 2B are circuit diagrams illustrating the reading operation for identifying bad blocks in the IC;

FIGS. 3A and 3B are schematic diagram illustrating a parallel arrangement of prior-art circuit of FIG. 1;

FIG. 4 is a circuit diagram system illustrating an electronic system for conditioning and identification of bad blocks in an IC, according to an exemplary embodiment of the present disclosure;

FIG. 5 is a schematic diagram illustrating a parallel arrangement of electronic systems, according to an exemplary embodiment of the present disclosure;

FIG. 6 is a circuit diagram system illustrating an electronic system for conditioning and identification of bad blocks in an IC, according to another exemplary embodiment of the present disclosure; and

FIG. 7 is a circuit diagram system illustrating an electronic system for conditioning and identification of bad blocks in an IC, according to another exemplary embodiment of the present disclosure.

Like reference numerals refer to like parts throughout the description of several views of the drawings.

### DETAILED DESCRIPTION OF THE DISCLOSURE

For a thorough understanding of the present disclosure, refer to the following detailed description, including the appended claims, in connection with the above-described drawings. Although the present disclosure is described in connection with exemplary embodiments, the disclosure is not intended to be limited to the specific forms set forth herein. It is understood that various omissions and substitutions of equivalents are contemplated as circumstances may suggest or render expedient, but these are intended to cover the application or implementation without departing from the spirit or scope of the claims of the present disclosure. Also, it is to be understood that the phraseology and terminology used herein is for the purpose of description and should not be regarded as limiting.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced item.

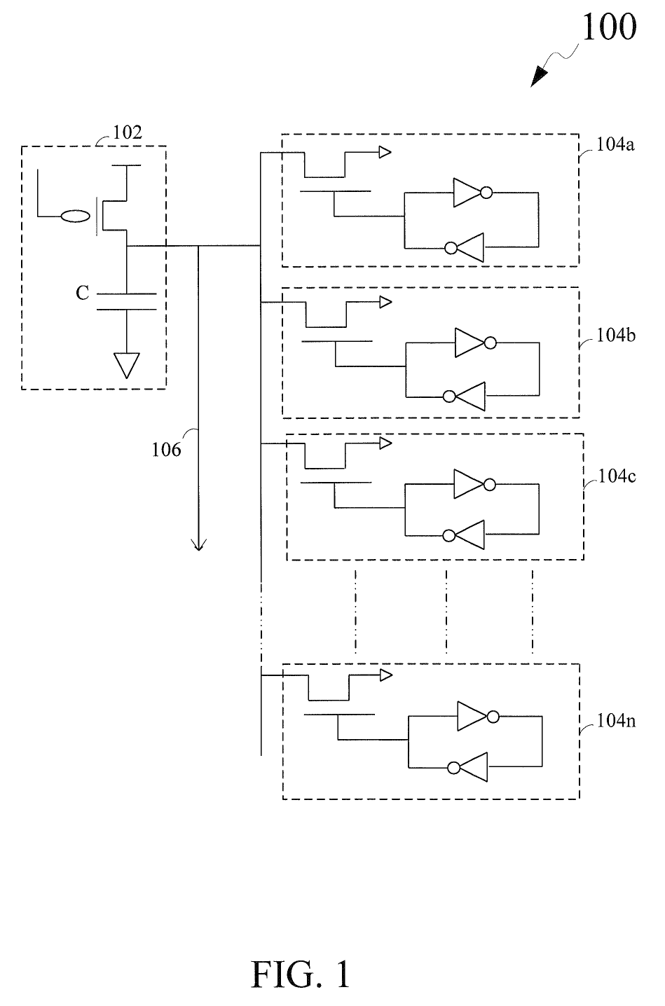

FIG. 1 is a circuit diagram illustrating a prior art circuit 100 used for a reading operation for identifying bad blocks in an Integrated Circuit (IC). The IC includes a plurality of blocks. Each block of the plurality of blocks may be associated with at least one latch. The prior art circuit 100 (hereinafter referred to as circuit 100) may be used to identify the bad blocks in the IC through the reading of the at least one latch associated with each of the plurality of blocks. The circuit 100 comprises: a pre-charging circuitry 102; a plurality of latches such as a latch 104a, a latch 104b, a latch 104c and up to a latch 104n; and a flag line 106. The prior art circuit 100 as shown in FIG. 1 is an exemplary representation only. The pre-charging circuitry 102 is connected to the latches 104a-104n (hereinafter collectively referred to as ‘latches 104’). The flag line 106 is configured to read logic bits stored in the latches 104.

The reading of the latches 104 comprises following steps. First, a parasitic capacitor (represented as ‘C’ in FIG. 1) of the pre-charging circuitry 102 is pre-charged to a pre-charge voltage. The purpose of the pre-charging is to bring the voltage level at the flag line 106 to a known voltage level that is the pre-charge voltage. Thereafter, a latch of the latches 104 is selected and the reading of the flag line 106 is performed. The voltage level at the flag line 106 is indicative of the content of the selected latch, which is the voltage at the capacitor ‘C.’ The capacitor ‘C’ discharges or remains charged based on the content of the selected latch.

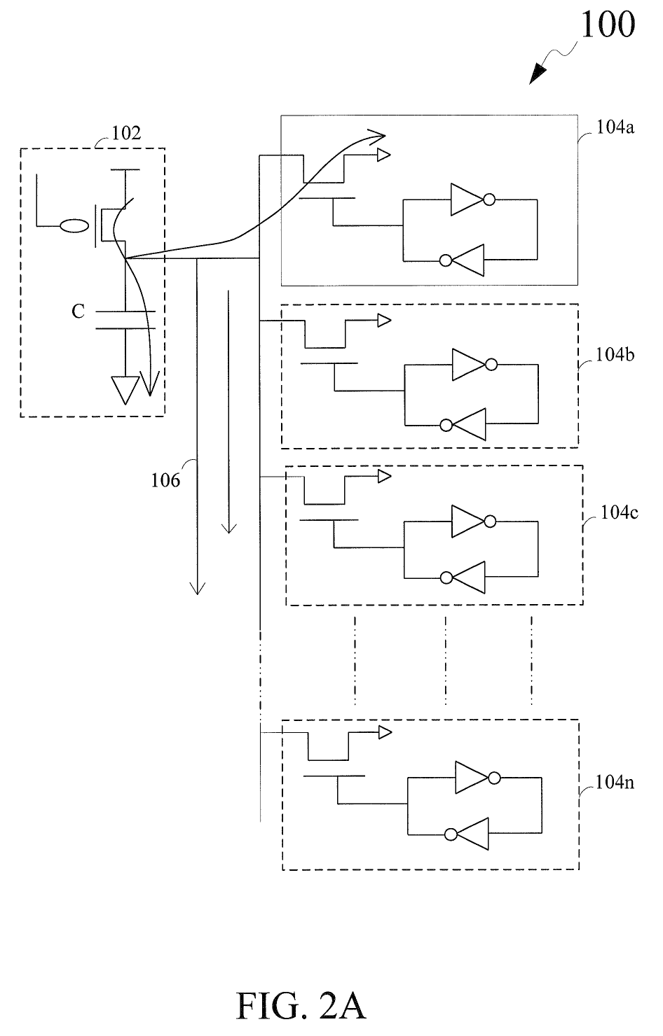

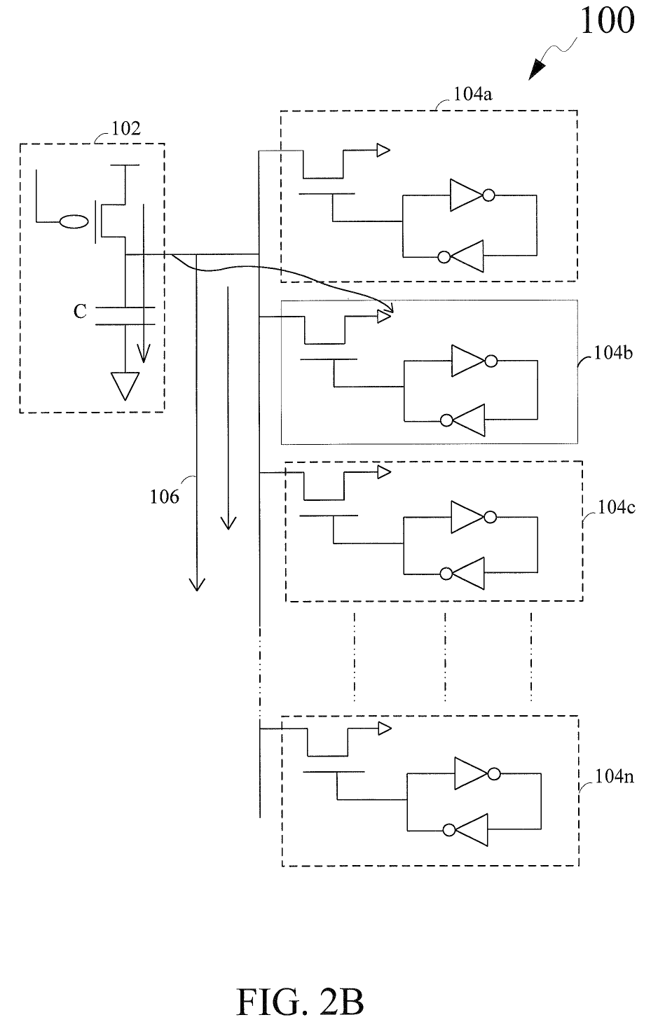

FIGS. 2A and 2B are circuit diagrams illustrating the reading operation for identifying the bad blocks in the IC. FIG. 2A represents the reading operation of the latch 104a. The reading of the latch 104a includes pre-charging the capacitor ‘C’ by the pre-charging circuitry 102 to the pre-charge voltage. Further, the latch 104a is selected. Based on the content of the latch 104a, the voltage level at the capacitor ‘C’ remains charged or is discharged. For example, let the content of the latch 104a be at a high logic level ‘1.’ In this case, the voltage level at the capacitor ‘C’ remains charged. Alternatively, the voltage level at the capacitor ‘C’ is discharged when the content of the latch 104b is at a low logic level ‘0.’ Similarly, FIG. 2B represents the reading operation of the latch 104b. Reading the content of the latch 104b comprises the same steps as performed to read the content of the latch 104a, i.e., pre-charging the capacitor ‘C’, selecting the latch 104b, and thereafter reading the flag line 106.

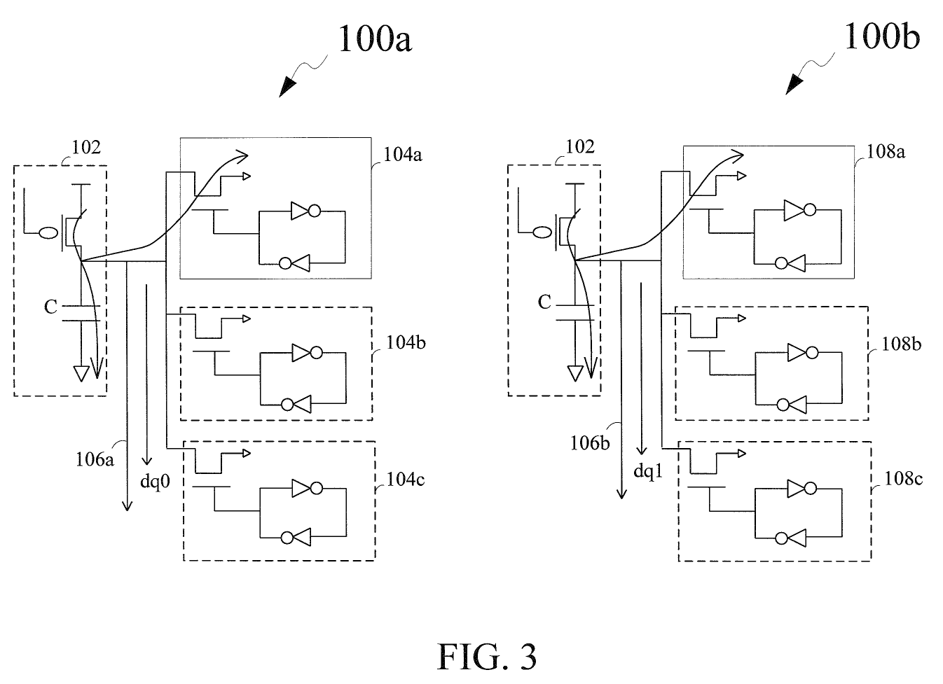

It will be obvious to a person skilled in the art that the reading operation for identifying the bad blocks using the prior-art circuit 100 is time consuming as only one latch is selected at a time for which the flag line 106 is read. Moreover, the pre-charge operation is performed each time a latch is selected. Further, the flag line 106 has a large capacitance which inhibits fast charging and discharging operation of the capacitor ‘C.’ However, a plurality of prior-art circuits 100 may be arranged in parallel for a faster reading operation for identifying the bad blocks in the IC. Such a concept is described below in conjunction with FIG. 3.

Referring now to FIG. 3, two circuits 100a and 100b (similar to the circuit 100), are shown. The two circuits 100a, 100b may be used in parallel in the IC, which in turn improves the performance of the reading operation for identifying the bad blocks in the IC. The parallel arrangement of the circuits 100a and 100b includes: coupling a set of latches 104a, 104b, 104c (collectively referred to as ‘latches 104’) to the pre-charging circuitry 102 in the circuit 102a; and coupling a set of latches 108a, 108b, 108c (collectively referred to as ‘latches 108’) to the pre-charging circuitry 102 in the circuit 102b. This arrangement uses several wide fan gates of the multiple set of latches 104 and latches 108. Each set of latches 104 and the latches 108 is connected to the pre-charging circuitry 102. Further, the output of the latches 104 and the latches 108 may be read on multiple flag lines 106a and 106b in a parallel fashion (shown by dq0 and dq1). The parallel arrangement of the prior-art circuits 100a and 100b improves the performance of the reading operation for identifying bad blocks. However, the limitations such as high capacitance of the flag line, reading of one latch of a set of latches at a time are still present.

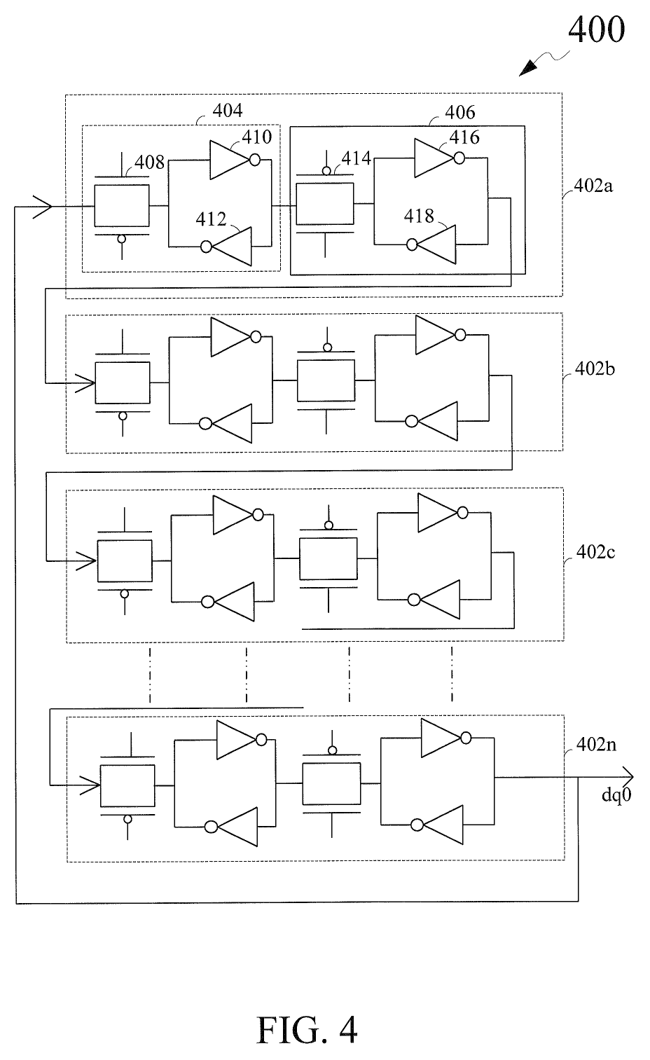

FIG. 4 is a circuit diagram system illustrating an electronic system 400 of an IC for conditioning and identification of bad blocks in the IC, according to an exemplary embodiment of the present disclosure. The electronic system 400 comprises a cyclic scan chain which includes a plurality of flip-flops. The plurality of flip-flops may include flip-flop 402a, flip-flop 402b, flip-flop 402c, . . . , flip-flop 402n. The plurality of flip-flops are collectively referred to as ‘flip-flops 402’. In an embodiment of the present disclosure, the flip-flops 402 are connected in a cascaded manner to form the cyclic scan chain. Accordingly, an output of a flip-flop of the flip-flops 402 may be configured to read logic bits present in the flip-flops 402. Each of the flip-flops 402 is composed of a master section and a slave section. For example, as shown in FIG. 4, the flip-flop 402a comprises a master section 404 and a slave section 406. In this exemplary embodiment of the present disclosure, the master section 404 of the flip flop 402a includes a transmission gate 408 and a pair of inverters 410 and 412. The inverters 410 and 412 are connected in a cyclic manner such that the master section 404 stores a logic bit by inverting the logic bit twice. Similarly, the slave section 406 includes a transmission gate 414 and a pair of inverters 416 and 418 connected in a cyclic manner. A clock signal in the IC is connected to the transmission gates of the master section 404 and the slave section 406 such that the master section 404 and the slave section 406 in combination function as a flip-flop.

The electronic system 400 may further comprise a plurality of preset/reset transistors (not shown in FIG. 4). In an embodiment of the present disclosure, a preset/reset transistor is coupled to each flip-flop of the flip-flops 402. The preset/reset transistor may be any of a preset or reset transistor or a combination of both. The preset/reset transistor is configured to condition the corresponding flip-flop to which the preset/reset transistor is coupled. In other words, the preset/reset transistor may be used to upload a desired logic bit pattern in the flip-flops 402. In operation, the preset/reset transistors may operate as follows: a)address a desired block (e.g., 402a, 402b, 402c, etc.), b) assert a preset/reset signal, c) wait, and d) de-assert the preset/reset signal.

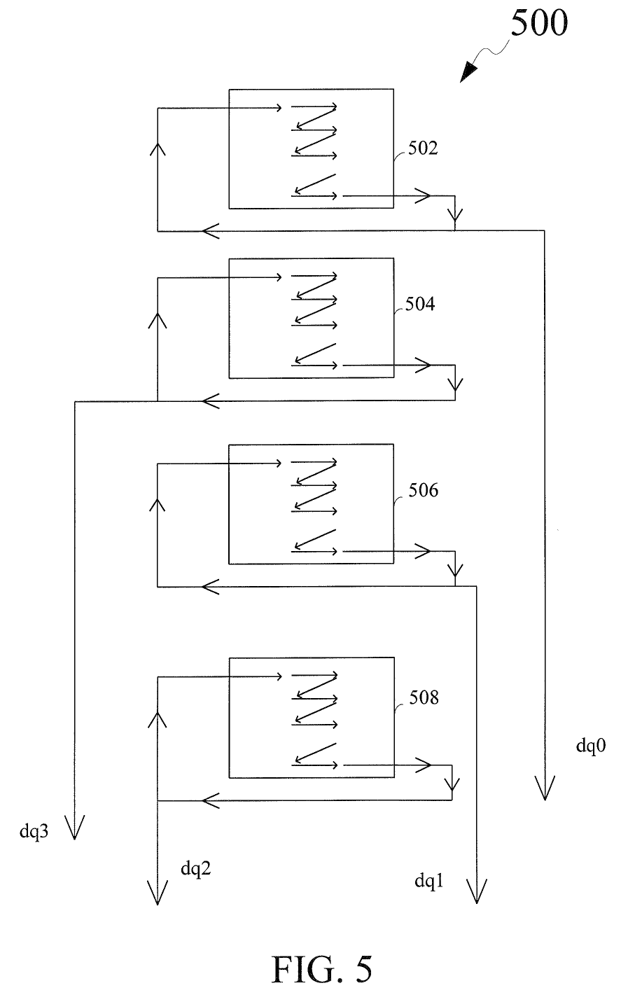

FIG. 5 is a schematic diagram illustrating a parallel arrangement of electronic systems 502, 504, 506, and 508, according to an exemplary embodiment of the present disclosure. In one embodiment, each of the electronic systems 502, 504, 506, and 508 is similar to the electronic system 400 as explained in conjunction with FIG. 4. It will be apparent to a person skilled in the art that using the parallel arrangement of electronic systems 502, 504, 506, and 508, the reading operation for identifying the bad blocks in multiple cyclic shift registers may be performed at the outputs dq0, dq1, dq2 and dq3 simultaneously, thereby further improving the performance of the reading operation.

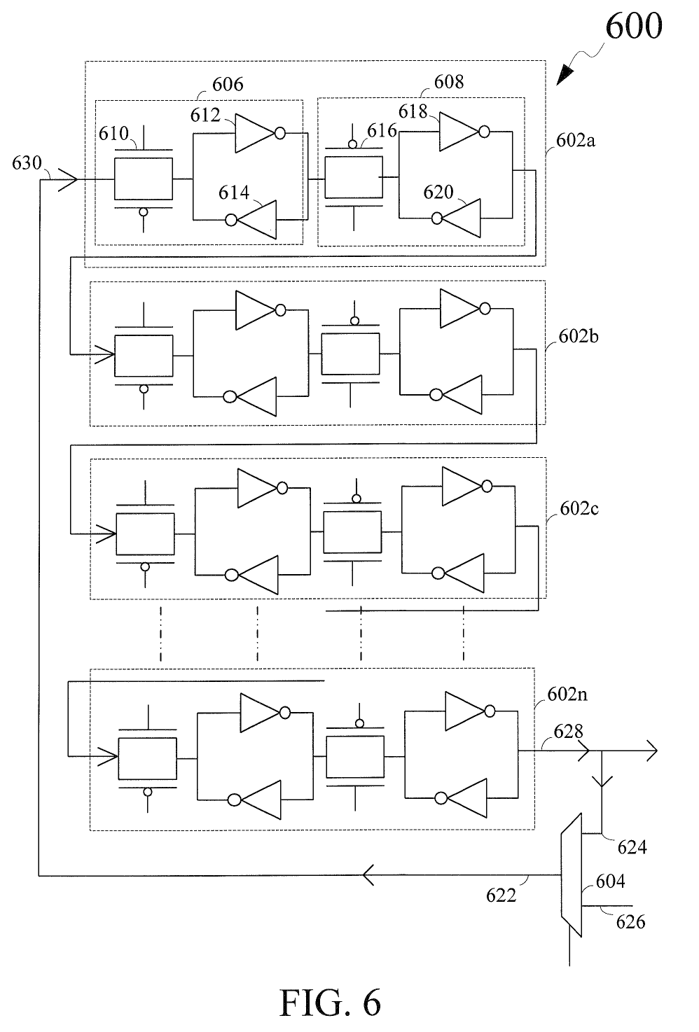

Referring now to FIG. 6, a circuit diagram system illustrating an electronic system 600 for conditioning and identification of bad blocks in an IC is shown, according to another exemplary embodiment of the present disclosure. The electronic system 600 comprises a cyclic shift register which includes a plurality of flip-flops 602a, 602b, and up to 602n (hereinafter collectively referred to as ‘flip-flops 602′). The flip-flops 602 are connected in a cascaded manner to form the cyclic shift register. Each of the flip flops 602 is composed of a master section and a slave section. For example, as shown in FIG. 6, the flip-flop 602a comprises a master section 606 and a slave section 608. In this exemplary embodiment of the present disclosure, the master section 606 of the flip flop 602a includes a transmission gate 610 and a pair of inverters 612 and 614. The inverters 612 and 614 are connected in a cyclic manner such that the master section 606 stores a logic bit by inverting the logic bit twice. Similarly, the slave section 608 includes a transmission gate 616 and a pair of inverters 618 and 620 connected in a cyclic manner. A clock signal in the IC is connected to the transmission gate 610 of the master section 606 and the transmission gate 616 of the slave section 608 such that the master section 606 and the slave section 608 in combination function as a flip-flop.

The electronic system 600 further comprises a multiplexer 604. The multiplexer 604 is coupled between two adjacent flip-flops, for example, between a first flip-flop 602a and a second flip-flop 602n (as shown in FIG. 6). The multiplexer 604 has an output pin 622 and two input pins (a first input pin 624 and a second input pin 626) The output pin 622 of the multiplexer 604 is connected to an input 630 of the first flip-flop 602a of the adjacent flip-flops. The first input pin 624 of the multiplexer 604 is connected to an output 628 of the second flip-flop 602n of the adjacent flip-flops. The second input pin 626 of the multiplexer 604 is configured to receive a desired pattern of logic bits. The desired pattern of logic bits may be provided through a user pin on the periphery of the IC.

The first input pin 624 is configured to pass the output of the second flip-flop 602n to the input 630 of the first flip-flop 602a, when the first input pin 624 of the multiplexer 604 is selected. In this case, the multiplexer 604 maintains the cyclic nature of the cyclic shift register. Further, the multiplexer 604 may be configured to condition the flip-flops 602 by passing the desired pattern of logic bits to the input 630 of the first flip-flop 602a upon selecting the second input pin 626. For example, to enable half of the flip-flops 602 (assuming the number of flip-flops 602 are 8), a pattern ‘11110000’ may be passed in the flip-flops 602 through the second input pin 626. Similarly, the pattern ‘10101010’ may be uploaded to enable the even or odd flip-flops of the flip-flops 602. It will be apparent to a person skilled in the art that the multiplexer 604 may be used to quickly set bad blocks in the test modes instead of the individual blocks by inserting a particular pattern of logic bits.

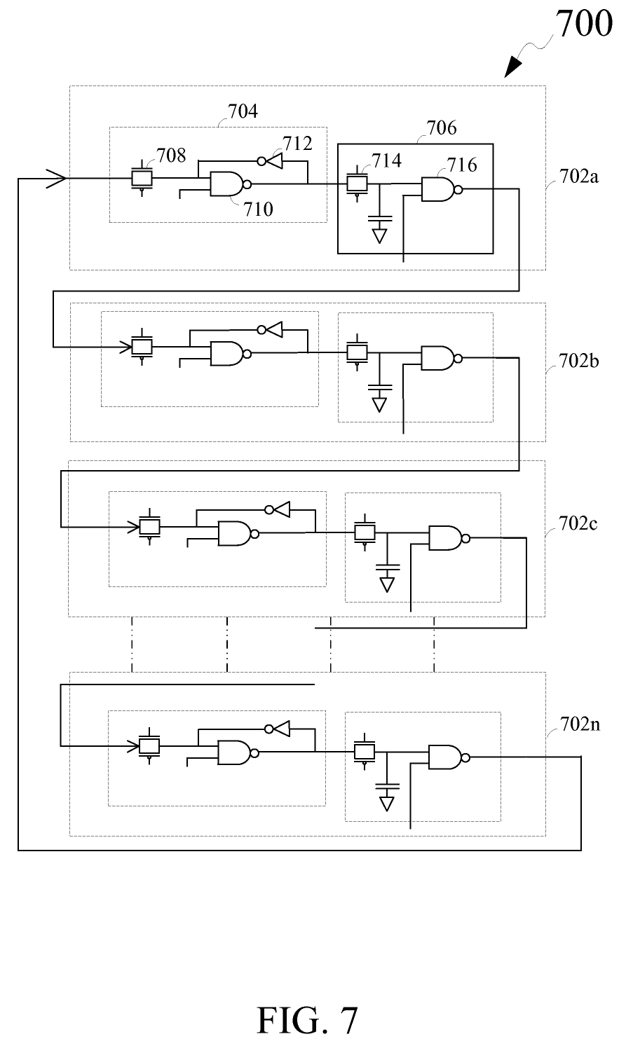

FIG. 7 is a circuit diagram system illustrating an electronic system 700 for conditioning and identification of bad blocks in an integrated circuit, according to another exemplary embodiment of the present disclosure. The electronic system 700 comprises a cyclic shift register which includes a plurality of flip-flops. The plurality of flip-flops includes a flip flop 702a, a flip-flop 702b and up to a flip-flop 702n. The plurality of flip-flops may be collectively referred to as ‘flip-flops 702.′ In an embodiment of the present disclosure, the flip-flops 702 are connected in a cyclic manner to form the cyclic shift register. Therefore, output of a flip-flop of the flip-flops 702 may be configured to read logic bits present in the flip-flops 702.

Each of the flip flops 702 is composed of a master section and a slave section of the flip-flop. For example, as shown in FIG. 7, the flip-flop 702a comprises a master section 704 and a slave section 706. In a user mode of operation in the IC, the slave section 706 does not interfere with the rest of the circuits in the IC, therefore, the slave section 706 may be composed as a dynamic latch. In this exemplary embodiment of the present disclosure, the master section 704 of the flip flop 702a is a static latch. This static latch may be configured by using at least one transmission gate, at least one NAND gate and at least one inverter. As shown in FIG. 7, the master section 704 includes a transmission gate 708, a NAND gate 710 and an inverter 712. The NAND gate 710 and the inverter 712 are connected in such a manner that the master section 704 stores a logic bit by performing the inverting operation by both the NAND gate 710 and the inverter 712. In this exemplary embodiment of the present disclosure, the slave section 706 is a dynamic latch. The dynamic latch may be configured by using at least one transmission gate and at least one inverter configuration. As shown in FIG. 7, the slave section 706 includes a transmission gate 714 and a NAND gate 716 (which acts as the inverter configuration). In another embodiment of the present disclosure, an inverter may be used at the place of NAND gate. It will be apparent to a person skilled in the art that the multiplexer 604 (as shown in FIG. 6) may be coupled between two adjacent flip-flops, such as, between a first flip-flop 702n and a second flip-flop 702a, which provides an option of conditioning the flip-flops by uploading desired logic bit pattern by the user pin.

Referring again to FIG. 5, the parallel arrangement 500 may also contain multiple electronic systems 600 arranged parallel to each other. In this arrangement, multiple reading operations of bad blocks may be performed simultaneously. Similarly, in another embodiment of the present disclosure, multiple electronic systems 700 may also be used in the parallel arrangement 500.

Various embodiments of the present disclosure offer following advantages. The use of electronic systems 400, 600, and 700 provides an improved performance of the conditioning and identification of bad blocks in an IC. These systems do not require pre-charging circuitry for the reading operation, which in turn, eliminates the process of pre-charging each time a bad block tag is read. Further, these systems use flip-flops in place of latches, which improves the synchronous nature of the IC as opposed in the case that latches are used. In a typical IC, blocks are placed abutting each other, which facilitates cascading of the flip-flops to make a cyclic shift resister in the electronic systems 400, 600, and 700. With the use of the multiplexer 604 in the electronic system 600, the use of preset/reset transistors may be avoided and a desired pattern can be uploaded in the flip-flops. The electronic systems 400, 600, and 700 may also be arranged as parallel arrangement 500 in the IC, which further improves the performance of the IC.

The foregoing descriptions of specific embodiments of the present disclosure have been presented for purposes of illustration and description. They are not intended to be exhaustive or to limit the disclosure to the precise forms disclosed, and obviously many modifications and variations are possible in light of the above teaching. The embodiments were chosen and described in order to best explain the principles of the disclosure and its practical application, to thereby enable others skilled in the art to best utilize the disclosure and various embodiments with various modifications as are suited to the particular use contemplated. It is understood that various omission and substitutions of equivalents are contemplated as circumstance may suggest or render expedient, but such are intended to cover the application or implementation without departing from the spirit or scope of the claims of the present disclosure.

What is claimed is:

1. An electronic system of an integrated circuit (IC) for conditioning and identification of bad blocks in the IC, the electronic system comprising:
at least one cyclic shift register, each cyclic shift register comprising a plurality of flip-flops connected in a cascaded manner; and
at least one multiplexer, each multiplexer connected between two adjacent flip-flops of a cyclic shift register of the at least one cyclic shift register, the each multiplexer comprising
an output pin connected to an input of a first flip-flop of the two adjacent flip-flops,
a first input pin connected to an output of a second flip-flop of the two adjacent flip-flops and configured to pass the output of the second flip-flop to the input of the first flip-flop, and
a second input pin configured to receive a desired pattern of logic bits;
wherein the each multiplexer is configured to condition the plurality of flip-flops by passing the desired pattern of logic bits to the input of the first flip-flop; and
wherein the output of the second flip-flop is configured to read logic bits in the plurality of flip-flops to identify a bad block in the IC.

2. The electronic system of claim 1, wherein cyclic shift registers of the at least one cyclic shift register are arranged parallel to each other.

3. The electronic system of claim 1, wherein each flip-flop of the cyclic shift register comprises a master section and a slave section.

4. The electronics system of claim 3, wherein each of the master section and slave section comprises at least one transmission gate and a pair of inverters.

5. The electronics system of claim 3, wherein the master section comprises at least one transmission gate, at least one NAND gate and at least one inverter.

6. The electronics system of claim 5, wherein the slave section comprises at least one transmission gate and at least one inverter configuration.

7. An electronic system of an integrated circuit (IC) for conditioning and identification of bad blocks in the IC, the electronic system comprising:
at least one cyclic shift register, each cyclic shift register comprising
a plurality of flip-flops connected in a cascaded manner, and
a plurality of preset/reset transistors, each preset/reset transistor coupled to a flip-flop of the plurality of flip-flops;
wherein the each present/reset transistor is configured to condition the flip-flop by programming a logic bit in the flip-flop; and
wherein an output of the flip-flop is configured to read logic bits in the plurality of flip-flops to identify the bad blocks in the IC.

8. The electronic system of claim 7, wherein cyclic shift registers of the at least one cyclic shift register are arranged parallel to each other.

9. The electronic system of claim 7, wherein each flip-flop of the plurality of flip-flops comprises a master section and a slave section.

10. The electronics system of claim 9, wherein each of the master section and the slave section comprises at least one transmission gate and two inverters.

11. The electronics system of claim 9, wherein the master section comprises at least one transmission gate, at least one NAND gate and at least one inverter.

12. The electronics system of claim 11, wherein the slave section comprises at least one transmission gate and at least one inverter configuration.

13. An electronic system of an integrated circuit (IC) for conditioning and identification of bad blocks in the IC, the electronic system comprising:
at least one cyclic scan chain, each cyclic scan chain comprising a plurality of flip-flops connected in a cascaded manner, each flip-flop comprising a master section and a slave section; and
at least one multiplexer, each multiplexer connected between two adjacent flip-flops of a cyclic scan chain of the at least one cyclic shift register, the each multiplexer comprising:
an output pin connected to an input of a first flip-flop of the two adjacent flip-flops,
a first input pin connected to an output of a second flip-flop of the two adjacent flip-flops and configured to pass the output of the second flip-flop to the input of the first flip-flop, and
a second input pin configured to receive a desired pattern of logic bits;
wherein the each multiplexer is configured to condition the plurality of flip-flops by passing the desired pattern of logic bits to the input of the first flip-flop; and
wherein the output of the second flip-flop is configured to read logic bits in the plurality of flip-flops to identify a bad block in the IC; and
wherein the master section is a static latch and the second latch is a dynamic latch.

14. The electronic system of claim 13, wherein cyclic scan chains of the at least one scan chain are arranged parallel to each other.
